(19) United States
(12) Patent Application Publication
(10) Pub. No.: US 2015/0111341 A1
(43) Pub. Date: Apr. 23, 2015

(54) LASER ANNEALING METHODS FOR INTEGRATED CIRCUITS (ICs)

(71) Applicant: QUALCOMM Incorporated, San Diego, CA (US)

(72) Inventors: Yong Ju Lee, San Diego, CA (US); Yang Du, Carlsbad, CA (US)

(73) Assignee: QUALCOMM Incorporated, San Diego, CA (US)

(21) Appl. No.: 14/149,882

(22) Filed: Jan. 8, 2014

Related U.S. Application Data
(60) Provisional application No. 61/894,547, filed on Oct. 23, 2013.

(51) Int. Cl. H01L 21/268; H01L 21/324

(52) U.S. Cl. CPC H01L 21/268; H01L 21/324
USPC 438/107; 438/799

(57) ABSTRACT

Laser annealing methods for integrated circuits (IC) are disclosed. In particular, an upper surface of an integrated circuit is annealed with a laser using a brief burst of light from the laser. In an exemplary embodiment, the brief burst of light from the laser lasts approximately fifty (50) to five hundred (500) microseconds. This brief burst will raise the temperature of the surface to approximately 1200° C.

### PRIORITY CLAIM

The present application claims priority to U.S. Provisional Patent Application Ser. No. 61/894,547 filed on Oct. 23, 2013 and entitled “LASER ANNEALING METHODS FOR MONOLITHIC THREE DIMENSIONAL (3D) INTEGRATED CIRCUITS (IC) (3DIC),” which is incorporated herein by reference in its entirety.

### BACKGROUND

I. Field of the Disclosure

The technology of the disclosure relates generally to forming integrated circuits (ICs).

II. Background

Mobile communication devices have become common in current society. The prevalence of these mobile devices is driven in part by the many functions that are now enabled on such devices. Demand for such functions increases processing capability requirements and generates a need for more powerful batteries. Within the limited space of the housing of the mobile communication device, batteries compete with the processing circuitry. The limited space contributes pressure to a continued miniaturization of components and desire for reduced power consumption by the circuitry. While miniaturization has been of particular concern in the integrated circuits (ICs) of mobile communication devices, efforts at miniaturization of ICs in other devices such as desk top computers have also occurred.

Historically, elements within an IC have all been placed in a single two dimensional (2D) active layer with elements interconnected through one or more metal layers that are also within the IC. Efforts to miniaturize ICs are reaching their limits in the 2D space and thus, design thoughts have moved to three dimensions. While there have been efforts to connect two or more ICs through a separate set of metal layers outside the IC proper, that solution is not properly a three dimensional (3D) approach. Another proposal has been to stack two IC chips atop one another with connections made between the two IC chips through solder bumps (i.e., the so called “flip chip” format). Likewise, there are system in package (SIP) solutions that stack IC chips atop one another with connections made between the chips with through silicon vias (TSVs). While arguably the flip chip and TSV embodiments represent 3D solutions, the amount of space required to effectuate a flip chip remains large. Likewise, the space required to implement a TSV relative to the overall size of the chip becomes space prohibitive.

Recent advances in 3D solutions include proposals relating to monolithic 3D integrated circuits (3DIC). While 3DIC solutions have allowed further miniaturization efforts, even within the 3DIC technology, difficulties in the manufacturing process have been discovered. In particular, as the physical channel length of metal oxide semiconductor field effect transistors (MOSFETs) used in active elements within the 3DIC decreases, the junction depth of source and drain regions must also be reduced to prevent unwanted source/drain to substrate junction capacitance. However, obtaining these smaller junction depths tests the capabilities of current processing techniques, such as an ion implantation with activation annealing using rapid thermal annealing (RTA). RTA typically involves heating the silicon wafer at over 1000° C. for several seconds, after implanting, under high density heat lamps. Implanting (or doping) amorphizes the silicon substrate, and the activation annealing is used to recrystallize the amorphized silicon region. This annealing temperature is too high for monolithic 3DIC applications which typically require that the temperature remain below 400° C. Temperatures above 400° C. adversely affect the previously formed active elements in the previously formed tiers. That is, a 3DIC is a series of tiers, each of which has active elements including fabricated transistors and interconnect metal layers. Once these elements are formed, exposure to elevated temperatures during formation of subsequent tiers may cause chemical or structural changes in the lower tiers which adversely impact performance.

### SUMMARY OF THE DISCLOSURE

Embodiments disclosed in the detailed description include laser annealing methods for integrated circuits (ICs). In particular, an upper surface of an IC is annealed with a laser using a brief burst of light from the laser. In an exemplary embodiment, the brief burst of light from the laser lasts approximately fifty (50) to five hundred (500) microseconds. This brief burst will raise the temperature of the surface to approximately 1200° C.

By providing this brief burst of thermal energy, a relatively small thermal budget is exhausted in such a manner that the metal layers of the IC are cured as desired with appropriate crystallization of the metal. Additionally, dopants are activated within the IC without providing so much thermal energy as would create problems with diffusion of the dopants. That is, the dopants are activated, but they do not diffuse through the substrate beyond a desired threshold. As a further advantage of the laser annealing process, defects in the interfacial oxide are repaired. As a further advantage, vacancy density is reduced in the silicon channel under a spacer for the gate of transistors. While applicable to ICs in general, embodiments of the present disclosure are well suited for use with three dimensional (3D) ICs (3DICs).

In this regard in one embodiment, a method of annealing a surface is disclosed. The method comprises directing a laser beam at the surface to raise the temperature of the surface to at least 1200° C. for approximately 50 to 500 microseconds.

In another exemplary embodiment, a method of forming a 3DIC is disclosed. The method comprises forming a first lower tier of the 3DIC with one or more active elements. The method also comprises adding a second upper tier of the 3DIC above the first lower tier. The method also comprises directing a laser beam at an upper surface of the second upper tier to raise the temperature of the upper surface to at least 1200° C. for approximately 50 to 500 microseconds.

### BRIEF DESCRIPTION OF THE FIGURES

FIG. 1 illustrates exemplary geometries of an active element within an integrated circuit (IC) that control performance of the IC;

FIG. 2 illustrates a graph of a conventional rapid thermal annealing (RTA) process that may be used to form an active element such as the active element of FIG. 1;

FIGS. 3A-3E illustrate exemplary by-products of using the RTA process of FIG. 2 to form an IC;

FIG. 4 illustrates an exemplary three dimensional (3D) IC (3DIC) with ICs that may formed through embodiments of the laser annealing processes of the present disclosure;

FIGS. 5A-5E illustrate exemplary conventional steps in an ion cutting process to assemble a 3DIC such as the 3DIC of FIG. 4;

FIG. 6 illustrates a flow chart setting forth an exemplary conventional process for ion cutting;

FIG. 7 is a flow chart setting forth an exemplary process for forming a 3DIC according to the present disclosure;

FIG. 8 is a graph versus time of the two step annealing process according to an exemplary embodiment of the present disclosure;

FIG. 9 is graph of drive current versus gate voltage for the laser annealing processes compared to the RTA process;

FIG. 10 is a cross-sectional view of the drain section of a transistor formed through exemplary laser annealing embodiments and highlighting the variable Xⱼ;

FIG. 11 is a graph of the vacancy density versus length for the laser annealing process compared to the RTA process;

FIG. 12 is a cross sectional view of an IC formed through exemplary embodiments of the laser annealing process of the present disclosure; and

FIG. 13 is a block diagram of an exemplary processor-based system that can include a 3DIC made according to the processes set forth herein.

### DETAILED DESCRIPTION

With reference now to the drawing figures, several exemplary embodiments of the present disclosure are described. The word “exemplary” is used herein to mean “serving as an example, instance, or illustration.” Any embodiment described herein as “exemplary” is not necessarily to be construed as preferred or advantageous over other embodiments.

Embodiments disclosed in the detailed description include laser annealing methods for integrated circuits (ICs). In particular, an upper surface of an IC is annealed with a laser using a brief burst of light from the laser. In an exemplary embodiment, the brief burst of light from the laser lasts approximately fifty (50) to five hundred (500) microseconds. This brief burst will raise the temperature of the surface to approximately 1200° C.

By providing this brief burst of thermal energy, a relatively small thermal budget is exhausted in such a manner that the metal layers of the IC are cured as desired with appropriate crystallization of the metal. Additionally, dopants are activated within the IC without providing so much thermal energy as would create problems with diffusion of the dopants. That is, the dopants are activated, but they do not diffuse through the substrate beyond a desired threshold. As a further advantage of the laser annealing process, defects in the interfacial oxide are repaired. As a further advantage, vacancy density is reduced in the silicon channel under a spacer for the gate of transistors. While applicable to ICs in general, embodiments of the present disclosure are well suited for use with three dimensional (3D) ICs (3DICs).

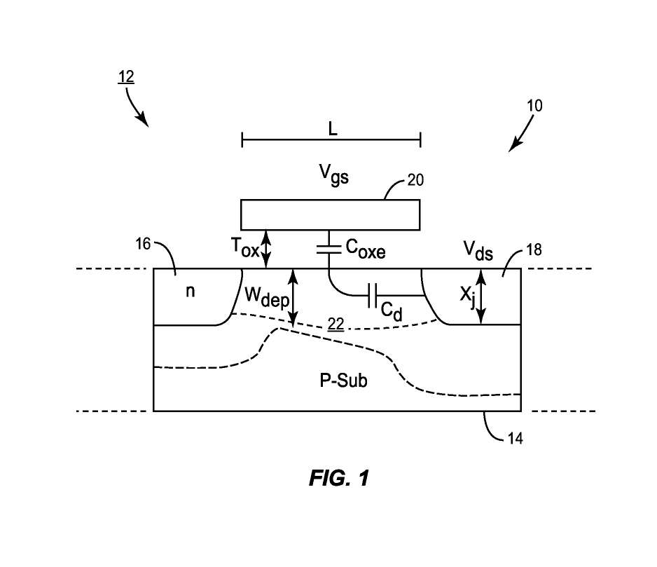

Before discussing embodiments of the process to anneal an active element within an IC, a brief overview of an exemplary active element 10 of an IC 12 is provided with reference to FIG. 1. As illustrated, the active element 10 is an n-p-n transistor on a substrate 14. The transistor has a source 16, a drain 18, and a gate 20 with a channel 22 between the source 16 and drain 18 as is well understood. The channel 22 has a length L. As L increases, leakage current (I_{off}) within the transistor decreases. Conversely, as L decreases, the leakage current will increase. As mentioned above, there is pressure within the industry to miniaturize every element within an IC. Thus, current designs make efforts to miniaturize the active element 10 within the IC 12 with a corresponding reduction in L. L_{off} becomes unacceptably large when the threshold voltage (Vₜ) becomes too small. Vₜ is defined by the following equation.

$${V}_{t} = {V}_{t \text{-} long} - ( {V}_{ds} + 0.4 ) * \frac{{C}_{d}}{{C}_{oxe}}$$

$$and$$

$${V}_{t} = {V}_{t \text{-} long} - ( {V}_{ds} + 0.4 ) * {e}^{\frac{- L}{{I}_{d}}}$$

$$where$$

$${I}_{d} is proportional to \sqrt[3]{{T}_{ox} {W}_{dep} {X}_{j}}$$

where Tₒₓ is the oxide thickness under the gate 20, W_{dep} is the depth of the p-dopant of the substrate 14 (i.e., P_{sub}) and Xⱼ is the depth of the n dopant in the drain 18. I_{d} was defined by Professor King at UC Berkeley in an article entitled “The End of CMOS Scaling” IEEE CIRCUITS AND DEVICES, Vol. 21, pp. 16-26, 2005.

To support the reduction of L at each new technology node (e.g. 22 nm, 14 nm, 10 nm, etc.), I_{d} must be reduced in proportion to L. This means a corresponding reduction in Tₒₓ, W_{dep} and/or Xⱼ. Current manufacturing techniques are experiencing difficulties achieving further reductions in any of these three variables. These difficulties are in part due to the annealing process that is used in the construction of active element 10.

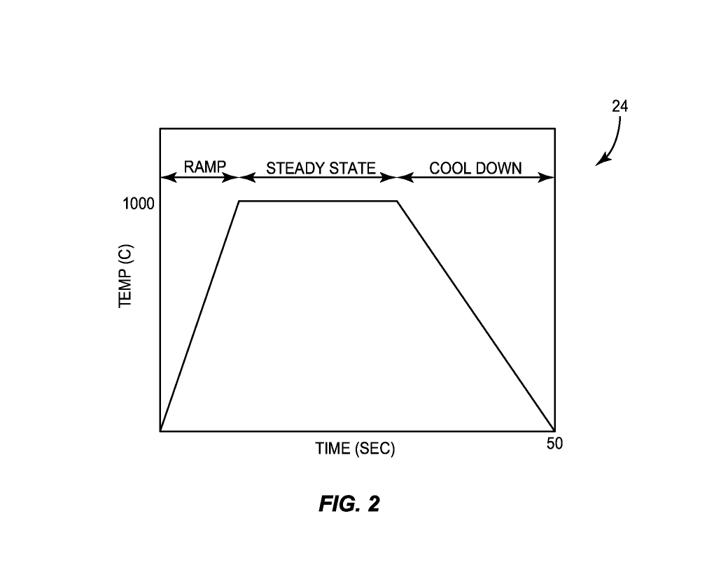

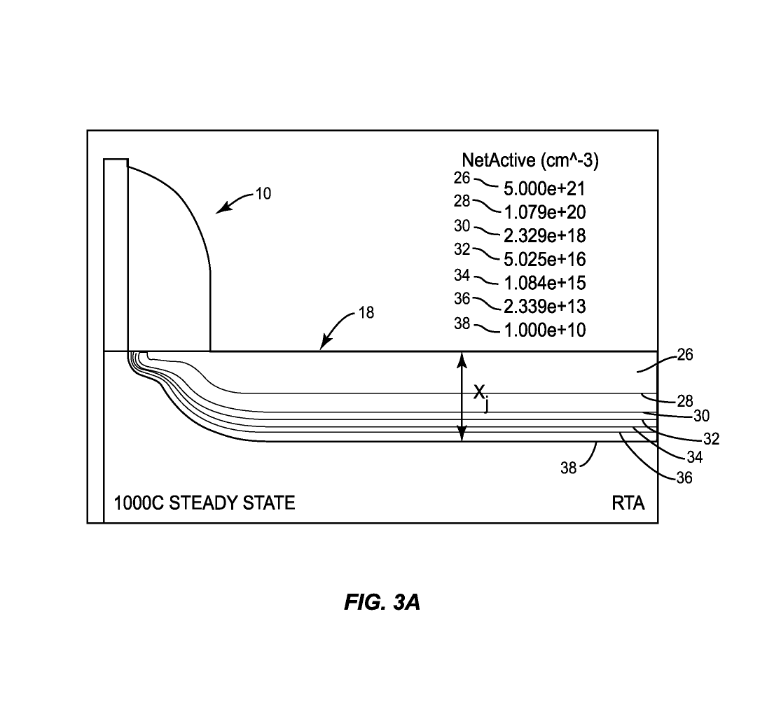

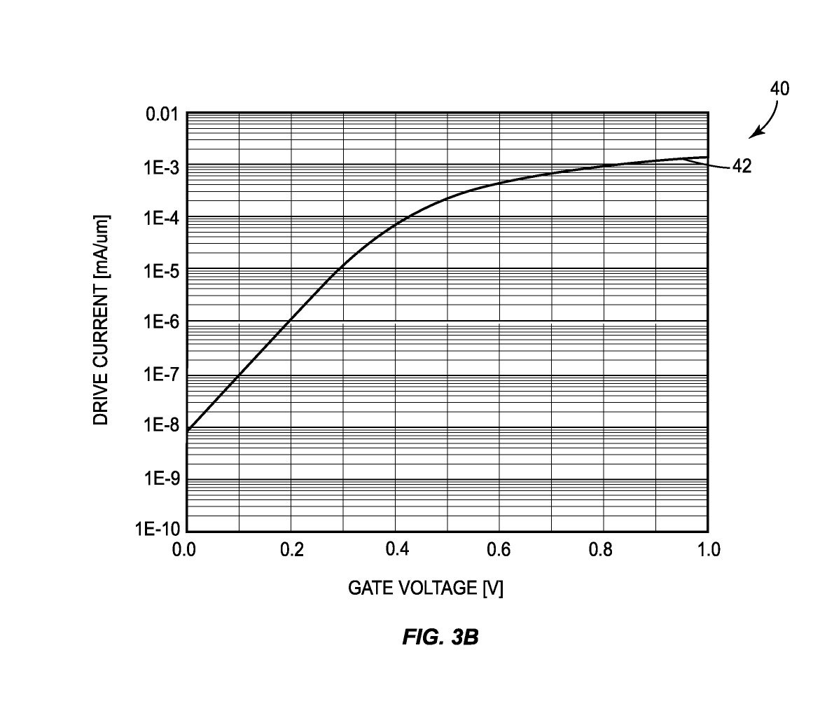

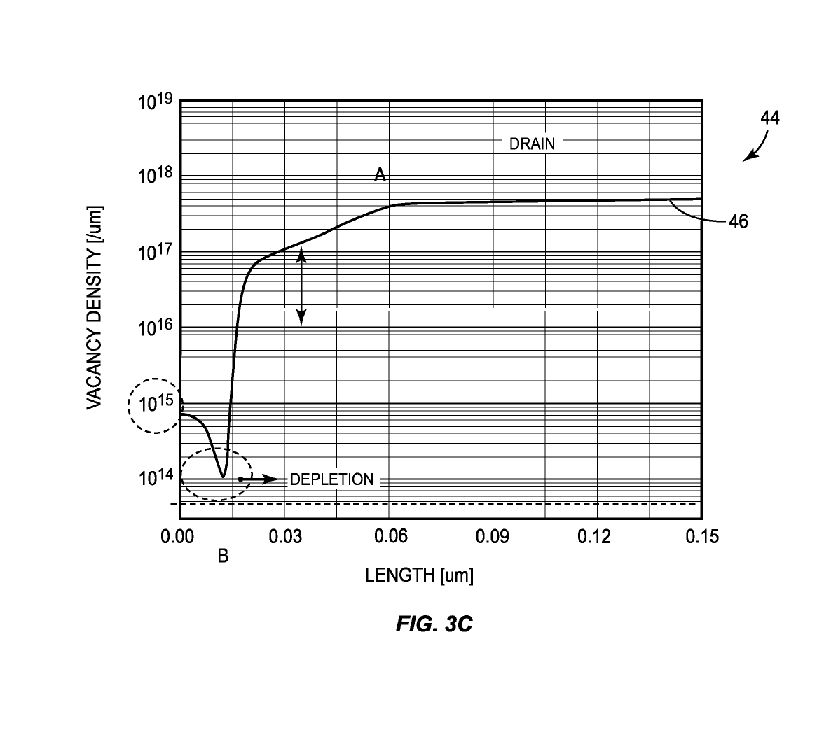

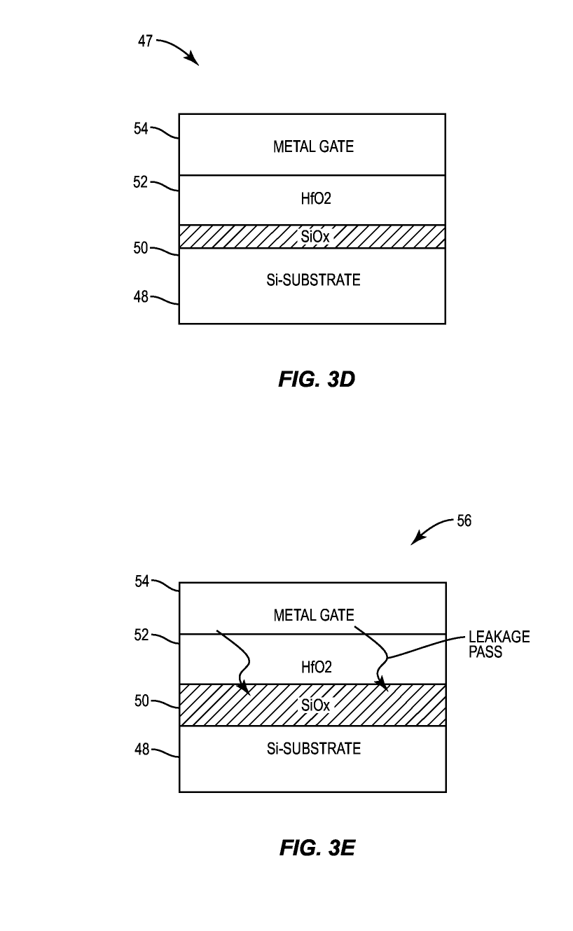

In an exemplary conventional process, a rapid thermal annealing (RTA) process is used to anneal the metal of the active element (e.g. active element 10). However, RTA processes have a large thermal budget which impairs optimal operation of the active element 10. A graph 24 of temperature versus time for an RTA process is provided in FIG. 2. In practice, heat lamps are applied to the active element 10 for some length of time, resulting in a gradual ramp up of temperature to around approximately 1000° C. This temperature is maintained for a period of time at a general steady state level, and then the lamps are removed, and the active element 10 cools down. The entire process may take approximately fifty (50) seconds. This amount of energy added (T) multiplied by the time (t) makes for a large thermal budget (T*t). Such a large thermal budget negatively impacts performance as better illustrated in FIGS. 3A-3E.

FIG. 3A illustrates a cross-sectional view of the active element 10 and particularly highlights the depth Xⱼ resulting from an RTA process. As illustrated, zone 26 is the area of maximum dopant concentration (i.e., 5.000e+21), and lines 28, 30, 32, 34, 36, and 38 reflect decreasing concentrations of dopants. The depth of line 38 is approximately 35 nm. Xⱼ of this magnitude causes too much leakage current for optimal operation at the current proposed channel lengths.

Likewise, FIG. 3B illustrates a graph 40 illustrating the drive current versus gate voltage to activate the transistor (e.g., a transistor within active element 10). The line 42 illustrates the drive current required for each gate voltage. As will be seen later, the values on line 42 are sub-optimal compared to values achieved using laser annealing embodiments of the present disclosure.

Likewise, FIG. 3C illustrates a graph 44, the vacancy density after RTA processes, assuming a vacancy density of 5.16E13/cm³ before annealing. Line 46 illustrates that, for most lengths of interest, the RTA process is inferior to levels achieved by embodiments of the present disclosure as better explained below.

Finally, FIGS. 3D and 3E illustrate how the RTA process affects the layers of the active element 10. That is, FIG. 3D illustrates the layers 47 of an active element 10 as deposited including a silicon (Si) substrate 48 (corresponding to substrate 14 of FIG. 1), an interfacial oxide (SiOₓ) layer 50, an insulator layer (HfO₂) 52, and a metal gate 54 (corresponding to gate 20 of FIG. 1). As deposited, the interfacial oxide layer 50 may be about 0.4 nm. When the layers 47 are subjected to a RTA process, layers 47 change to layers 56 illustrated in FIG. 3E, where the insulator layer recrystallizes causing the interfacial layer 50 to grow. In typical processes, an interfacial oxide layer 50 that begins as 0.4 nm grows to approximately 0.7 nm. The recrystallization of the insulator layer 52 increases current leakage. Both the increased thickness and the increased current leakage are undesirable.

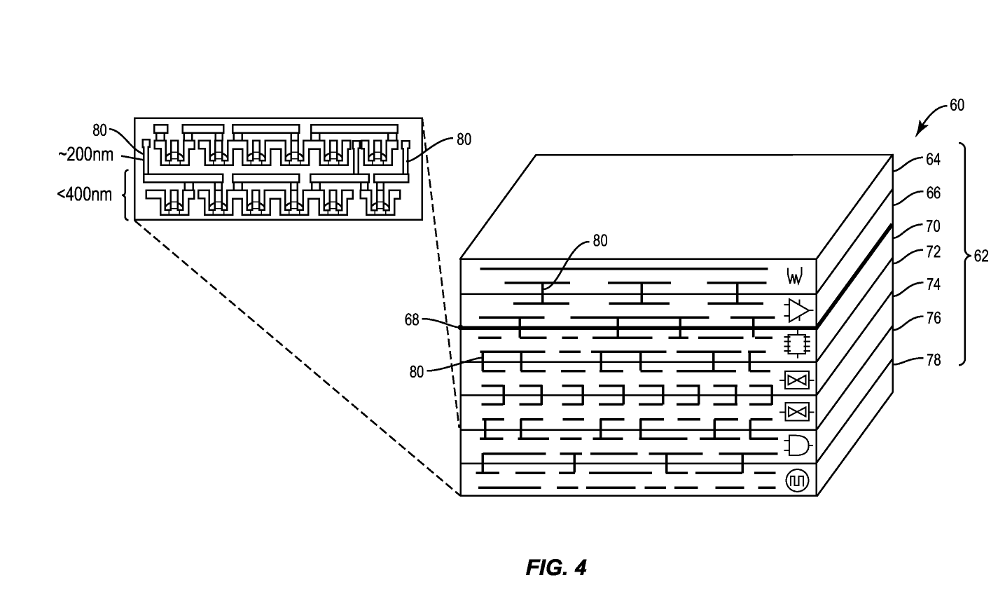

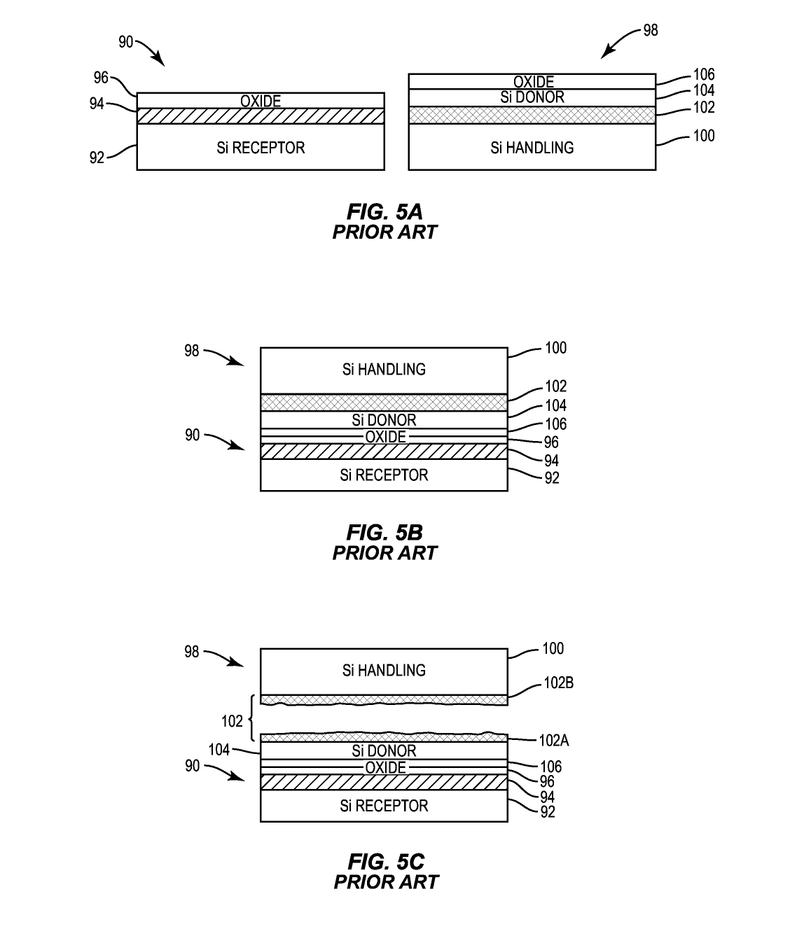

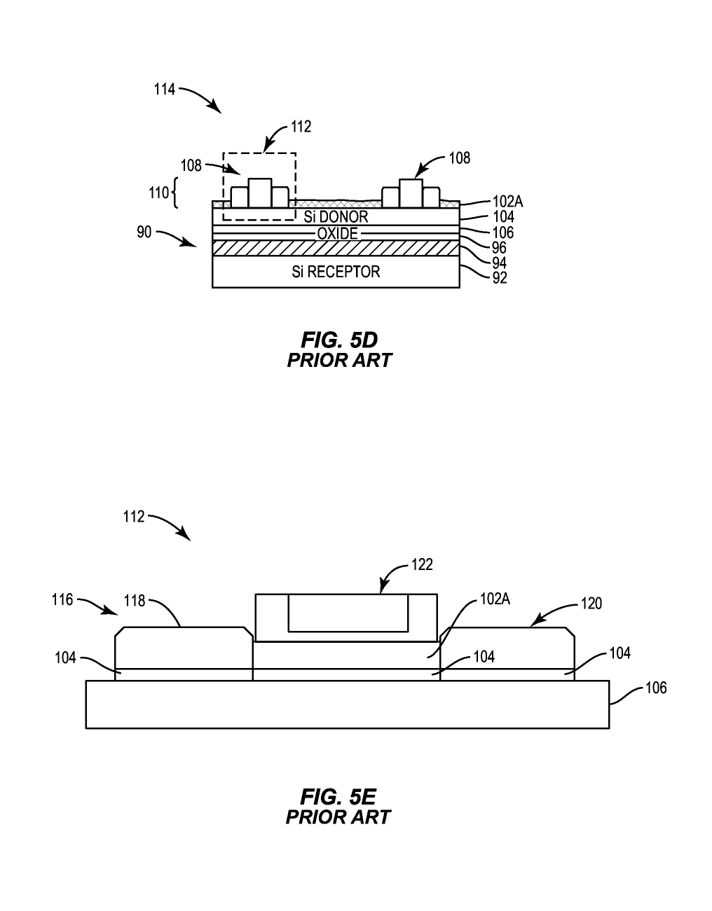

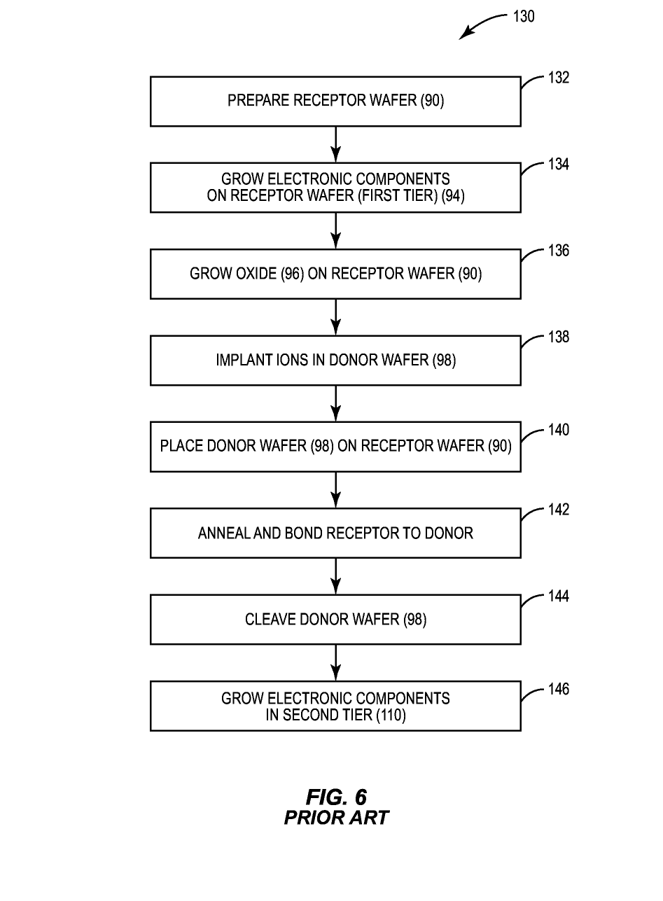

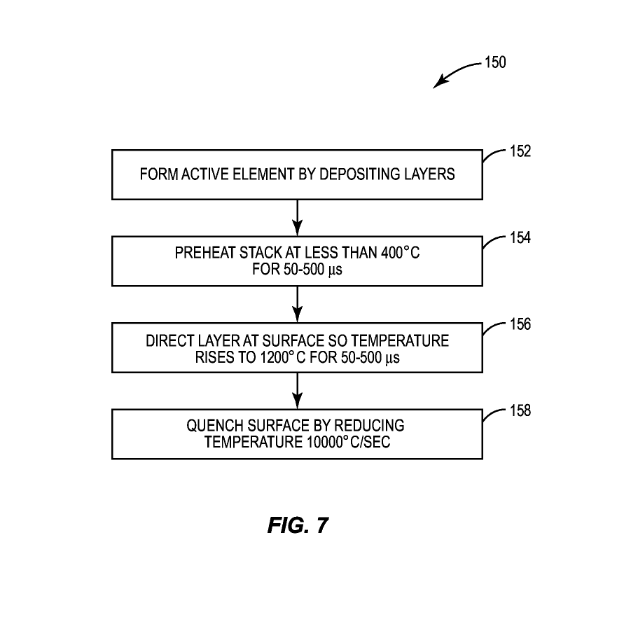

The problems generated in an IC through a RTA process are exacerbated in a 3DIC environment. Before addressing the particular problems that a RTA process generates in a 3DIC environment, a brief overview of a 3DIC is provided with reference to FIG. 4. Likewise, a brief overview of a conventional ion cutting process used in the assembly of a 3DIC is provided with reference to FIGS. 5A-5E and 6. The discussion of exemplary embodiments of a laser annealing process during the assembly of a 3DIC begins below with reference to FIG. 7.

In this regard, FIG. 4 is a simplified cross section of a 3DIC 60. The 3DIC 60 has multiple tiers 62. The tiers 62 may be formed by hydrogen cutting or other monolithic tier formation method. For more information on an exemplary hydrogen cutting process, the interested reader is referred to U.S. patent application Ser. No. 13/765,080, filed Feb. 12, 2013, which is herein incorporated by reference in its entirety.

The use of 3DIC technology allows different tiers of the tiers 62 within the 3DIC 60 to perform different functions and provides all of the functions of a particular device in a single 3DIC 60. For example, the 3DIC 60 may be a RF transceiver and controller for a mobile terminal. Thus, a first tier 64 includes sensors and other large feature size elements.

With continued reference to FIG. 4, a second tier 66 may include radio frequency, analog and/or power management integrated circuit (PMIC) components such as a receiver, transmitter, and duplexer/switch. The second tier 66 may be designed to be relatively low noise so that incoming RF analog signals are not distorted.

With continued reference to FIG. 4, an electromagnetic (EM) shield 68 may be positioned between the second tier 66 and a third tier 70. The EM shield 68 may be formed from a conductive material such as a graphene layer. For more information about graphene shields in 3DIC, the interested reader is referred to U.S. patent application Ser. No. 13/765,061, filed Feb. 12, 2013, the disclosure of which is herein incorporated by reference in its entirety.

The presence of the EM shield 68 helps prevent noise from the first and second tiers 64, 66 from affecting the low noise characteristics of the third tier 70. The third tier 70 may have a modem or other controller. To accommodate the functions on the third tier 70, the materials and design of the third tier 70 may be selected to promote a medium speed architecture.

With continued reference to FIG. 4, fourth and fifth tiers 72, 74 may be a memory bitcell array with random access memory (RAM) including dynamic RAM (DRAM), static RAM (SRAM) or the like. Both tiers 72, 74 may be designed to provide low leakage circuitry to improve the operation of the RAM.

With continued reference to FIG. 4, sixth and seventh tiers 76, 78 may be general processing unit tiers. Sixth tier 76 may include a digital signal processor (DSP) such as a baseband processor using combination logic while seventh tier 78 may include a DSP relying on sequential logic. Both tiers 76, 78 may be designed to support high speeds over concerns about leakage.

In an exemplary embodiment, the tiers are electrically intercoupled by monolithic intertier vias (MIV) 80. For more information about MIV, the interested reader is referred to “High-Density Integration of Functional Modules Using Monolithic 3D-IC Technology” by Shreedpad Panth et al. in the proceedings of the IEEE/ACM Asia South Pacific Design Automation Conference, 2013; pp. 681-686 which is hereby incorporated by reference in its entirety. In contrast to through silicon vias (TSV), MIV may be on the order of sub 100 nm in diameter (i.e., much smaller than the micron dimensions of the TSV) and 200 nm or less depth. Further, in an exemplary embodiment, each of the multiple tiers 62 may be approximately 400 nm thick or thinner. These dimensions are illustrated in the inset of FIG. 4.

While full system on a chip (SOC) embodiments are possible with 3DIC as illustrated by the 3DIC 60 of FIG. 4, other smaller ICs may also use 3DIC techniques. Such smaller ICs may have fewer tiers, but still be 3DIC by having two or more tiers. It is readily apparent that 3DIC such as 3DIC 60 provide many functions in a relatively small package and are helpful in meeting design criteria constrained by miniaturization pressures. However, these many functions are provided by providing active elements (e.g., active element 10) on each of the multiple tiers 62. For a better understanding of how a 3DIC 60 is constructed, reference is made to FIGS. 5A-5E and 6.

In this regard, FIG. 5A illustrates a first step of a conventional process to create a 3DIC (e.g. 3DIC 60). Specifically, a receptor wafer 90 is provided having a substrate 92 such as a silicon (Si) substrate. The substrate 92 may be referred to as a substrate means. A first tier of electronic components (e.g., active elements, generically indicated at 94) are grown on the substrate 92 as is well known. An oxide layer 96 is grown over the electronic components 94. Concurrently a donor wafer 98 is prepared. The donor wafer 98 may be referred to as a donor means. The donor wafer 98 may also be a silicon material. The donor wafer 98 is implanted with ions to form an ionized region 102, which effectively separates a handling portion 100 from a donor portion 104. Conventional implantation processes allow the creation of a localized, high concentration zone (sometimes called a Delta implant zone). In an exemplary process, the ions are hydrogen ions. An oxide layer 106 is grown on the donor portion 104.

With reference to FIG. 5B, the donor wafer 98 is stacked on top of the receptor wafer 90 such that the oxide layer 96 is in contact with the oxide layer 106. The oxide layers 96, 106 bond and are annealed through a relatively low temperature process (e.g., between approximately 250° C. and 350° C.). Following annealing, the donor wafer 98 is cleaved from the receptor wafer 90 as illustrated in FIG. 5C. The oxide layer 106, the donor portion 104, and a cleaved portion 102A of the ionized region 102 remain attached to the receptor wafer 90 and a residual portion 102B of the ionized region 102 remains on the handling portion 100 of the donor wafer 98 as is well understood.

After cleaving, with reference to FIG. 5D additional electronic components 108, such as transistors (e.g., active elements 10) are grown on the donor portion 104 to form a second tier of electronic components 110. Additional tiers (e.g., tiers 72) of electronic components beyond the second tier of electronic components 110 may be created by repeating the process to create a multi-level or multi-tier 3DIC. A portion 112 of the 3DIC 114 is illustrated in isolation in FIG. 5E, but is also shown within the 3DIC 114 in FIG. 5D to provide context.

With reference to FIG. 5E, the portion 112 of the 3DIC 114 illustrates a transistor 116 having a source 118, a drain 120, and a gate 122. The gate 122 is disposed on the cleaved portion 102A.

With FIGS. 5A-5E providing a visual depiction of an exemplary conventional ion cutting process 130, this conventional ion cutting process 130 is further presented in flow chart form in FIG. 6. The conventional ion cutting process 130 begins with the preparation of the receptor wafer 90 (block 132). Preparation of the receptor wafer 90 involves preparing the substrate 92 and may involve doping, curing, cutting, or other techniques as is well understood. Once prepared, a first tier of electronic components 94 are grown on the receptor wafer 90 (block 134). Once the electronic components 94 are grown, an oxide layer 96 is grown on the receptor wafer 90 (block 136, see also FIG. 5A).

With continued reference to FIG. 6, concurrently or sequentially, ions are implanted in the donor wafer 98 to form the ionized region 102 (block 138, see also FIG. 5A). As noted above, the ions are, in an exemplary embodiment, hydrogen ions. Oxide layer 106 is grown on the donor wafer 98 as well. The donor wafer 98 is placed on the receptor wafer 90 (block 140, see also FIG. 5B). The stack of donor wafer 98 and receptor wafer 90 is annealed (typically at a temperature range of approximately 250 to 350° C.) (block 142), fusing the oxide layers 96, 106. The annealing takes place until cracking of the ionized region 102 takes place, which enables the transfer of a donor portion 104 and cleaved portion 102A from the donor wafer 98 to the receptor wafer 90. This transfer is referred to as cleaving the donor wafer 98 (block 144, see also FIG. 5C). In exemplary methodologies the donor portion 104 is approximately 1.3 μm thick. Following the transfer, a second tier of electronic components 110 may be grown on the donor portion 104 (block 146, see also FIG. 5D). As should be appreciated, some portion of the cleaved portion 102A will be incorporated into or underneath individual ones of the additional electronic components 108.

As noted in FIG. 5D, transistors are positioned above one another in stacked tiers within the 3DIC. During the formation of the transistors, an annealing process is used to activate the dopants in the source and drain to the desired depth (i.e., Xⱼ). As noted above, such annealing processes typically occur through RTA, which takes place at approximately 1000° C. for time periods measured in seconds. If such annealing is used, the high temperature of the RTA damages the components of the lower tiers. That is, while the high temperatures may anneal the uppermost layer, heat diffuses and conducts down to lower tiers where further heat may damage the structures previously created. For example, metal layers providing interconnections between active elements may melt and lose desired routing configurations. Likewise, crystal lattices of layers within lower tiers may be changed (e.g., dopants may diffuse further than originally intended) by the additional heat.

The present disclosure proposes a laser annealing process that is well suited for use with upper tiers formed in a 3DIC but whose applicability may be extended to general IC formation. In an exemplary embodiment, a surface is preheated to a level below 400° C. and then rapidly heated to approximately 1200° C. and then rapidly cooled at a speed of approximately 10000° C. per second. While the peak temperature may be higher than conventional processes, the duration of the heat application is substantially shorter than conventional processes and accordingly, the thermal budget of the process is lower than conventional RTA processes. By maintaining such a low thermal budget, many of the disadvantages of conventional processes are avoided. In particular, the operational integrity of the lower tiers of a 3DIC is preserved.

FIG. 7 provides a flow chart for an annealing process 150 used in the formation of an active element. This annealing process may be inserted after block 136 or block 146 of the process 130 (FIG. 6) and is distinct from the annealing process of block 142 (FIG. 6). Thus, with reference to FIG. 7, the process 150 starts by forming active elements (e.g., active element 10) by depositing layers (block 152). The stack of layers is then preheated, such as through the use of a halogen heat lamp to less than approximately (or closely approximately) 400° C. for approximately 50-500 μs (block 154). As used herein “approximately” is plus or minus 5%. As further used herein, “closely approximately” is plus or minus 1%. Note that the preheating step of block 154 is optional. After preheating, or if block 154 is skipped, a laser is directed at an upper surface of the active element for approximately 50 to 500 μs such that the temperature of the surface rises to approximately 1200° C. (block 156). An exemplary laser for use in block 154 is described in U.S. Pat. No. 8,357,620, owned by Sony Corporation, which is hereby incorporated by reference in its entirety. After use heating with the laser, the surface is quenched rapidly at approximately 10000° C./second (block 158).

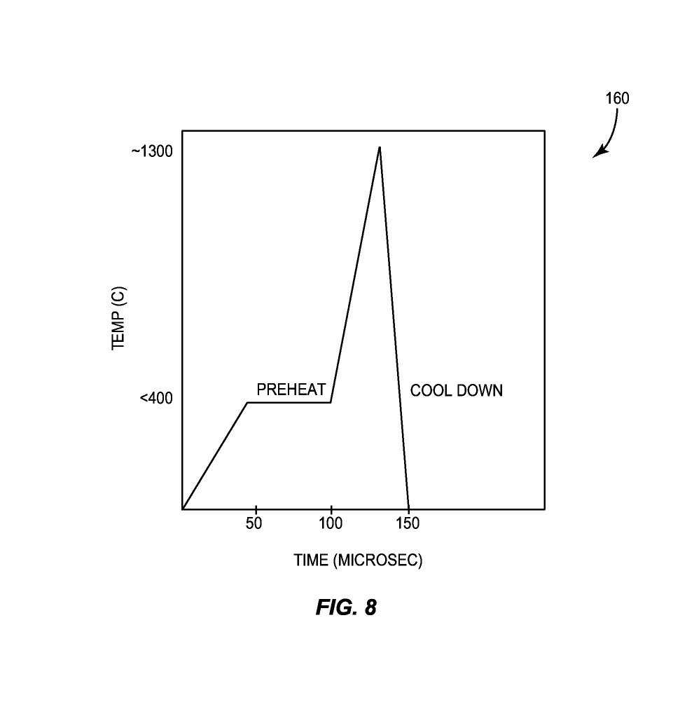

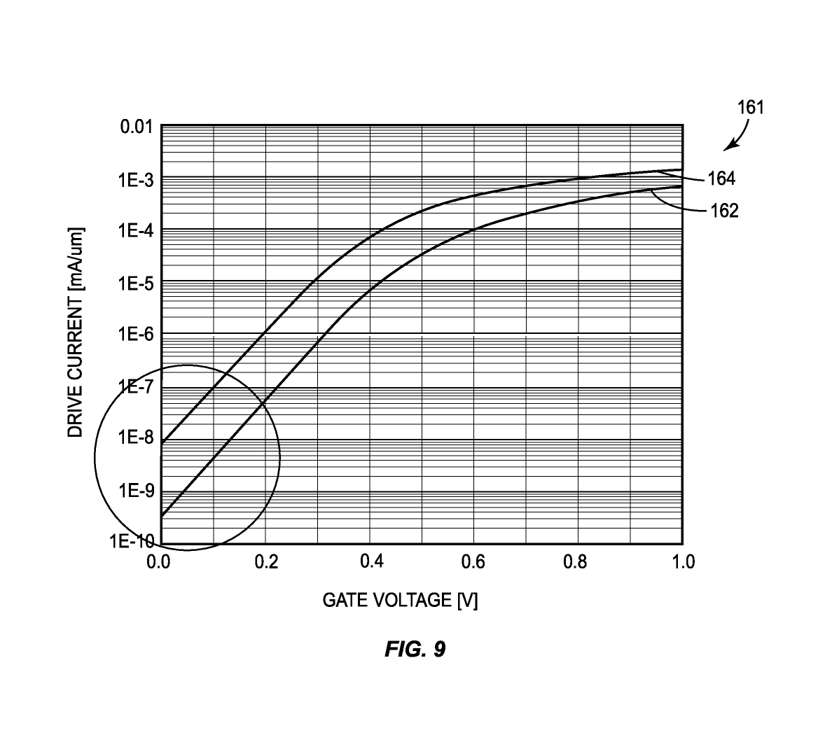

Use of the annealing process 150 results in a temperature versus time graph 160 illustrated in FIG. 8. Given the relatively short times of preheating and laser use, the total thermal budget of the process 150 is substantially smaller than the RTA process. Accordingly, there is less energy available to change active elements within the lower tiers of a 3DIC. Likewise, even in a simple 2D IC, the use of the annealing process 150 allows for greater control in the activation of dopants, which results in a correspondingly greater control of the depth of Xⱼ, improved drive current characteristics, preservation of thin interfacial thickness, and improved vacancy density.

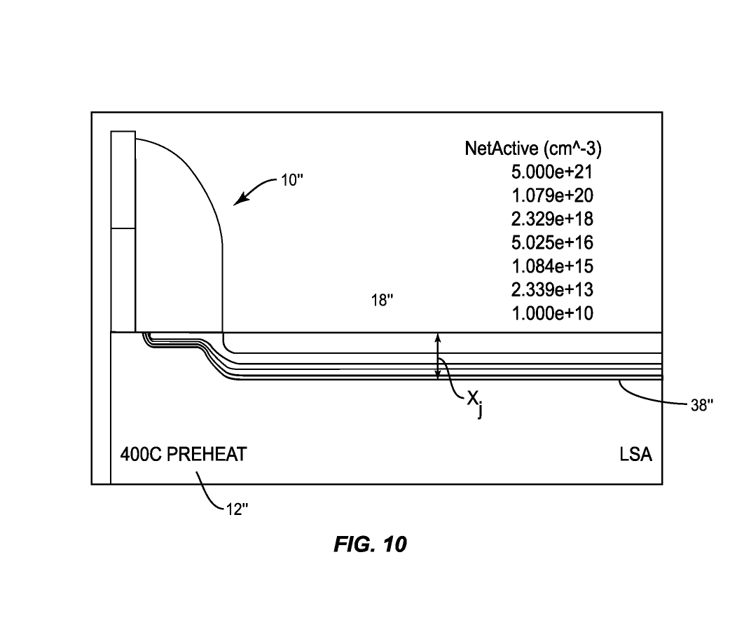

The advantages of the laser annealing process 150 are illustrated graphically with reference to FIGS. 9-12. In particular, FIG. 9 is a graph 160 of the drive current versus gate voltage comparable to FIG. 3B. Line 162 shows the values achieved through the laser annealing process 150 compared to line 164, which has the values achieved through an RTA process (duplicating line 42 from FIG. 3B). Likewise, FIG. 10 illustrates the depth of Xⱼ after a laser annealing process 150. Laser annealing process 150 activates the dopants within the drain 18″ of the active element 10″, but the thermal budget is small enough that the dopants do not diffuse through the substrate 12″. In an exemplary embodiment, the depth 38″ of the activation of the dopant is 15 nm.

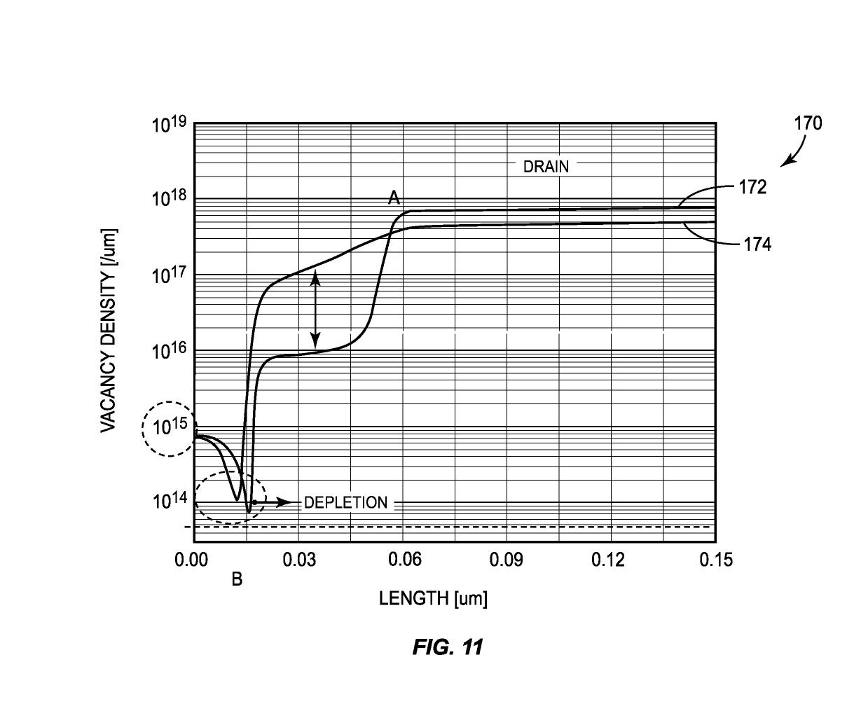

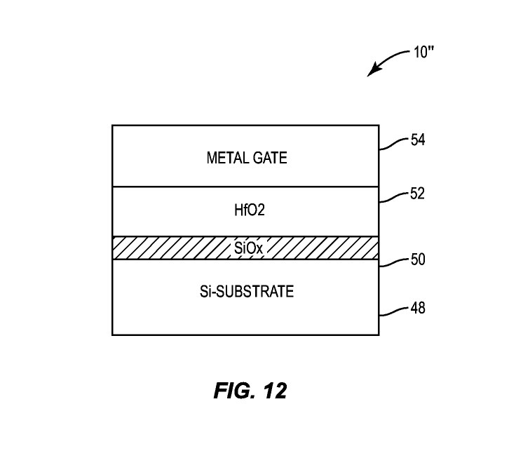

The improvement in the defect density is illustrated in FIG. 11, where graph 170 shows vacancy density versus length. Over the region of interest, line 172 for the laser annealing process 150 is better than line 174 of the RTA process. Likewise, the improvement in the interfacial oxide is illustrated in FIG. 12, where the interfacial oxide remains at approximately 0.4 nm (instead of the 0.7 nm of the RTA process (see FIG. 3E)).

The use of the laser annealing instead of the RTA of the prior art improves the diffusion of dopants while preserving the integrity of active elements within the lower tiers. Accordingly, improvements in the geometries of the transistors are effectuated and miniaturization may proceed.

The 3DIC according to embodiments disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

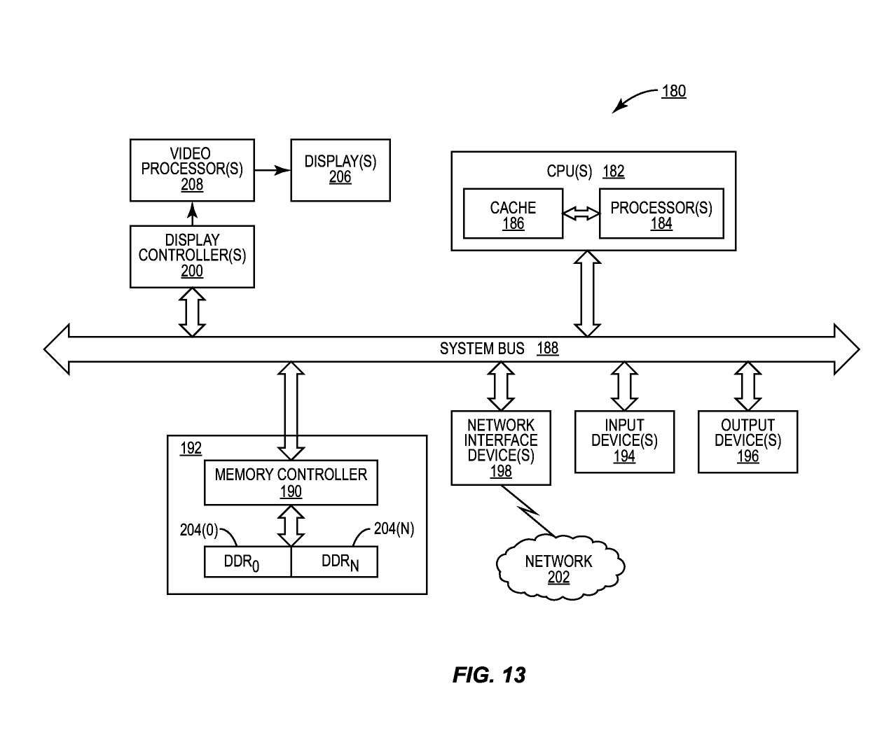

In this regard, FIG. 13 illustrates an example of a processor-based system 180 that can employ an IC or a 3DIC made with the laser annealing process 150. In this example, the processor-based system 180 includes one or more central processing units (CPUs) 182, each including one or more processors 184. The CPU(s) 182 may have cache memory 186 coupled to the processor(s) 184 for rapid access to temporarily stored data. The CPU(s) 182 is coupled to a system bus 188. As is well known, the CPU(s) 182 communicates with these other devices by exchanging address, control, and data information over the system bus 188. For example, the CPU(s) 182 can communicate bus transaction requests to the memory controller 190.

Other devices can be connected to the system bus 188. As illustrated in FIG. 13, these devices can include a memory system 192, one or more input devices 194, one or more output devices 196, one or more network interface devices 198, and one or more display controllers 200, as examples. The input device(s) 194 can include any type of input device, including but not limited to input keys, switches, voice processors, etc. The output device(s) 196 can include any type of output device, including but not limited to audio, video, other visual indicators, etc. The network interface device(s) 198 can be any device configured to allow exchange of data to and from a network 202. The network 202 can be any type of network, including but not limited to a wired or wireless network, private or public network, a local area network (LAN), a wide local area network (WLAN), and the Internet. The network interface device(s) 198 can be configured to support any type of communication protocol desired. The memory system 192 can include one or more memory units 204(0-N).

The CPU(s) 182 may also be configured to access the display controller(s) 200 over the system bus 188 to control information sent to one or more displays 206. The display controller(s) 200 sends information to the display(s) 206 to be displayed via one or more video processors 208, which process the information to be displayed into a format suitable for the display(s) 206. The display(s) 206 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the embodiments disclosed herein may be implemented as electronic hardware, instructions stored in memory or in another computer-readable medium and executed by a processor or other processing device, or combinations of both. The arbiters, master devices, and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the embodiments disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The embodiments disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A method of annealing a surface, comprising:
directing a laser beam at the surface to raise the temperature of the surface to at least 1200° C. for approximately 50 to 500 microseconds.

2. The method of claim 1, further comprising forming a transistor on the surface.

3. The method of claim 2, wherein forming the transistor comprises forming the transistor in an integrated circuit (IC).

4. The method of claim 3, wherein forming the transistor in the IC comprises forming the transistor in a three dimensional (3D) integrated circuit (3DIC) and the surface is associated with an upper tier of the 3DIC.

5. The method of claim 4, further comprising not elevating a lower tier within the 3DIC above 400° C. while directing the laser beam at the surface.

6. The method of claim 1, further comprising activating a dopant in the surface with the laser beam.

7. The method of claim 1, further comprising preheating the surface at a temperature less than 400° C.

8. The method of claim 1, wherein preheating comprises preheating the surface with a heat source for approximately 50 to 500 microseconds.

9. The method of claim 1, further comprising rapidly quenching the surface after directing the laser beam at the surface.

10. The method of claim 9, wherein rapidly quenching comprises changing the temperature at a speed of 10000° C. per second.

11. A method of forming a three dimensional (3D) integrated circuit (IC) (3DIC), comprising:
forming a first lower tier of the 3DIC with one or more active elements;
adding a second upper tier of the 3DIC above the first lower tier; and
directing a laser beam at an upper surface of the second upper tier to raise the temperature of the upper surface to at least 1200° C. for approximately 50 to 500 microseconds.

12. The method of claim 11, further comprising forming an upper active element in the second upper tier.

13. The method of claim 12, wherein forming the upper active element comprises forming a transistor.

14. The method of claim 13, further comprising controlling vacancy density beneath an element of the transistor to below a predefined threshold.

15. The method of claim 11, further comprising maintaining the first lower tier below approximately 400° C. while directing the laser beam at the upper surface.

16. The method of claim 11, further comprising activating a dopant in the upper surface with the laser beam.

17. The method of claim 11, further comprising preheating the upper surface at a temperature less than 400° C.

18. The method of claim 11, wherein preheating comprises preheating the upper surface with a heat source for approximately 50 to 500 microseconds.

19. The method of claim 11, further comprising rapidly quenching the upper surface after directing the laser beam at the upper surface.

20. The method of claim 19, wherein rapidly quenching comprises changing the temperature at a speed of 10000° C. per second.
